(19) United States
(12) Patent Application Publication
(10) Pub. No.: US 2016/0268230 A1
(43) Pub. Date: Sep. 15, 2016

(54) STACKED SEMICONDUCTOR STRUCTURE

(71) Applicant: United Microelectronics Corp., Hsin-Chu City (TW)

(72) Inventors: Sin-Shien Lin, Taipei City (TW); Fei Wang, Singapore (SG); Chien-En Hsu, Hsinchu County (TW)

(21) Appl. No.: 14/656,704

(22) Filed: Mar. 12, 2015

(51) Int. Cl. H01L 25/065; H01L 23/532; H01L 23/48; H01L 23/00; H01L 23/522; H01L 23/528

(52) U.S. Cl. CPC H01L 25/0657; H01L 23/5226; H01L 23/528; H01L 23/481; H01L 24/09; H01L 23/53295; H01L 2225/06541; H01L 2224/08146; H01L 2224/08148; H01L 2924/05042; H01L 2924/059; H01L 2924/05442

(57) ABSTRACT

A stacked semiconductor structure includes a first wafer, a second wafer, a first insulting layer, and a second insulating layer. The first wafer includes a first front surface, a first back surface, and a first interconnection structure. The first interconnection structure includes at least a first top metal layer exposed on the first front surface of the first wafer. The second wafer includes a second front surface, a second back surface, and a second interconnection structure. The second interconnection structure includes at least a second top metal layer exposed on the second front surface of the second wafer. The first insulating layer is formed on the first front surface of the first wafer, and the second insulating layer is formed on the second front surface of the second wafer. The first insulating layer and the second insulating layer contact each other.

### BACKGROUND OF THE INVENTION

1. Field of the Invention

The present invention relates to a stacked semiconductor structure, and more particularly, to a stacked semiconductor structure with wafers bonded together.

2. Description of the Prior Art

In an effort to increase the density and functionality of a semiconductor chip, attempts have been made to create three-dimensional integrated circuits (hereinafter abbreviated as 3D-ICs). Generally, 3D-ICs includes a plurality of semiconductor dies stacked upon each other, such as one semiconductor wafer/die bonded on top of another semiconductor wafer/die. The wafers/dies may include different functionalities or simply increase the density of a single functionality, such as a memory.

Accordingly, 3D-ICs may include two wafers bonded together through suitable wafer bonding techniques. Wafer bonding involves aligning two wafers parallel to each other, bringing them in contact with each other and then applying heat and force to the aligned stack of the two wafers. Furthermore, wafer-to-wafer, chip-to-wafer, or chip-to-chip (all used interchangeable herein) bonding require high precision alignment. It is found that when the wafers to be bonded are misaligned, the contact pads/layers exposed on one surface of the bonded wafers often contact the other wafer, and thus metal diffusion is caused. Consequently, electrical performance of the whole wafer level package is adversely impacted due to the metal diffusion contamination.

### SUMMARY OF THE INVENTION

According to an aspect of the present invention, a stacked semiconductor structure is provided. The stacked semiconductor structure includes a first wafer, a second wafer, a first insulting layer, and a second insulating layer. The first wafer includes a first front surface, a first back surface opposite to the first front surface, and a first interconnection structure formed in the first wafer. The first interconnection structure includes at least a first top metal layer exposed on the first front surface of the first wafer. The second wafer includes a second front surface, a second back surface opposite to the second front surface, and a second interconnection structure formed in the second wafer. The second interconnection structure includes at least a second top metal layer exposed on the second front surface of the second wafer. The first insulating layer is formed on the first front surface of the first wafer, and the second insulating layer is formed on the second front surface of the second wafer. More important, the first insulating layer and the second insulating layer contact each other.

According to another aspect of the present invention, a stacked semiconductor structure is provided. The stacked semiconductor structure includes a first wafer, a second wafer, a first interconnection structure formed in the first wafer, and a second interconnection formed in the second wafer. The first wafer include a first front surface and a first back surface opposite to each other, and the second wafer includes a second front surface and a second back surface opposite to each other. The first interconnection structure includes at least a first top metal layer protruded from the first front surface of the first wafer, and the second interconnection structure includes at least a second top metal layer protruded from the second front surface of the second wafer. More important, the second top metal layer directly contacts the first top metal layer.

According to still another aspect of the present invention, a stacked semiconductor structure is provided. The stacked semiconductor structure includes a first wafer, a second wafer, a solid insulating layer sandwiched between the first wafer and the second wafer, and a through-silicon-via (hereinafter abbreviated as TSV) structure penetrating the first wafer and the second wafer. The first wafer includes a first front surface, a first back surface opposite to the first front surface, and a first interconnection structure formed in the first wafer. The first interconnection structure includes at least a first top metal layer exposed on the first front surface of the first wafer. The second wafer includes a second front surface, a second back surface opposite to the second front surface, and a second interconnection structure formed in the second wafer. The second interconnection structure includes at least a second top metal layer exposed on the second front surface of the second wafer. The solid insulating layer is sandwiched between the first front surface of the first wafer and the second front surface of the second wafer.

According to the stacked semiconductor structure provided by the present invention, an insulating layer is always formed in between the first front surface of the first wafer and the second front surface of the second wafer. The insulating layer can be a solid insulating layer or an air insulating layer. More important, the insulating layer serves as a superior barrier for metal diffusion. Accordingly, in a case that the first wafer and the second wafer are unwantedly misaligned, the insulating layer prevents metal diffusion between the two bonded wafers . And thus electrical performance of the stacked semiconductor structure is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS . 1A, 1B and 2 are schematic drawings illustrating a stacked semiconductor structure provided by a first preferred embodiment of the present invention.

FIG. 3 is a schematic drawing illustrating a stacked semiconductor structure provided by a modification to the first preferred embodiment of the present invention.

FIGS. 4A, 4B and 5 are schematic drawings illustrating a stacked semiconductor structure provided by a second preferred embodiment of the present invention.

FIG. 6 is a schematic drawing illustrating a stacked semiconductor structure provided by a modification to the first and second preferred embodiments of the present invention.

### DETAILED DESCRIPTION

Please refer to FIGS. 1A, 1B and 2, which are drawings illustrating a stacked semiconductor structure provided by a first preferred embodiment of the present invention. As shown in FIG. 1A and FIG. 1B, the preferred embodiment provides a first wafer 100A and a second wafer 100B. The first wafer 100A and the second wafer 100B are to be bonded to form a stacked semiconductor structure such as a 3D-IC according to the preferred embodiment. The first wafer 100A can include a first substrate 102A, and at least an electronic circuitry (not shown) is formed in the first substrate 102A.

The electronic circuitry formed in the first substrate 102A includes circuitry for constructing any specific device/structure such as, for example but not limited to, memory structures, processing structures, sensors, amplifiers, power distribution, input/output circuitry, or the like. Generally, the electronic circuitry includes semiconductor devices (not shown) such as n-typed metal-oxide semiconductor (hereinafter abbreviated as nMOS) transistor devices and p-typed metal-oxide semiconductor (hereinafter abbreviated as pMOS) transistor devices, capacitors, resistor, diodes, fuses and/or any suitable devices. Those semiconductor devices may be electrically connected to perform one or more functions. The first wafer 100A further includes a first interconnection structure 110A providing the abovementioned electrical connections between the devices or electrical connections to external circuitry.

Please still refer to FIG. 1A, the first interconnection structure 110A includes a plurality of first dielectric layers 112A. The first dielectric layers 112A includes, low-K dielectric material, silicon oxide (SiO), phosphosilicate glass (PSG), borophosphosilicate glass (BPSG), fluorinated silicate glass (FSG), or tetra ethyl ortho silicate (TEOS), but not limited to this. The first interconnection structure 110A includes a plurality of first metal layers 114A formed in the first dielectric layers 112A, a plurality of first via plugs 116A formed in the first dielectric layers 112A, and at least a first top metal layer 118A. As shown in FIG. 1A, the first via plugs 116A electrically connect the first metal layers 114A and the first top metal layer 118A. The first metal layers 114A, the first via plugs 116A and the first top metal layer 118A can be formed by single and/or dual damascene processes. The first metal layers 114A, the first via plugs 116A and the first top metal layer 118A can include any suitable conductive material such as metal. For example but not limited to, the first metal layers 114A, the first via plugs 116A and the first top metal layer 118A can include Cu, W, or the like. Additionally, barrier layers (not shown) for prevention diffusion can be formed in between the first dielectric layers 112A and the first metal layers 114A, the first via plugs 116A and the first top metal layer 118A.

Please still refer to FIG. 1A. More important, the first wafer 100A includes a first insulating layer 120A formed thereon. An etching rate of the first insulating layer 120A is different from an etching rate of the first dielectric layers 112A. The first insulating layer 120A can include, for example but not limited to, a silicon nitride (hereinafter abbreviated as SiN) insulating layer or a silicon carbon nitride (hereinafter abbreviated as SiCN) insulating layer. The first insulating layer 120A includes a first thickness T₁, and the first thickness T₁ is between 100 angstroms (Å) and 800 Å. Preferably, the first thickness T₁ of the first insulating layer 120A is between 300 Å and 400 Å, but not limited to this. Usually, the first insulating layer 120A is an etching stop layer in a planarization process for forming the first top metal layer 118A. Accordingly, the first wafer 100A includes a first front surface 104A (which is meanwhile a surface of the first insulating layer 120A and a surface of the first top metal layer 118A) and a first back surface 106A opposite to the first front surface 104A, as shown in FIG. 1A. It should be easily realized that the first top metal layer 118A serves as an external contact pads allowing the first wafer 100A being electrically connected to other structure/circuitry/wafer. Therefore, the first top metal layer 118A is exposed on the first front surface 104A of the first wafer 100A. Additionally speaking, the surface of the first top metal layer 118A and the surface of the first insulating layer 120A are coplanar.

Please refer to FIG. 1B. The second wafer 100B can include a second substrate 102B, and at least an electronic circuitry (not shown) is formed in the second substrate 102B. The electronic circuitry formed in the second substrate 102B includes circuitry for constructing any specific device/structure such as, for example but not limited to, memory structures, processing structures, sensors, amplifiers, power distribution, input/output circuitry, or the like. According to the preferred embodiment, the second substrate 102B can include back side illumination (hereinafter abbreviated as BSI) sensors, but not limited to. The second wafer 100B further includes a second interconnection structure 110B providing the electrical connections between the devices or electrical connections to external circuitry.

Please still refer to FIG. 1B, the second interconnection structure 110B includes a plurality of second dielectric layers 112B. The second dielectric layers 112B can include material the same with those used to form the first dielectric layers 112A, therefore those details are omitted herein in the interest of brevity. The second interconnection structure 110B includes a plurality of second metal layers 114B formed in the second dielectric layers 112B, a plurality of second via plugs 116B formed in the second dielectric layers 112B, and at least a second top metal layer 118B. As shown in FIG. 1B, the second via plugs 116B electrically connect the second metal layers 114B and the second top metal layer 118B. The manufacturing process and material choice of the second metal layers 114B, the second via plugs 116B and the second top metal layer 118B can be the same with those used to form the first metal layers 114A, the first via plugs 116A and the first top metal layer 118A, therefore those details are also omitted for simplicity.

Please still refer to FIG. 1B. More important, the second wafer 100B includes a second insulating layer 120B formed thereon. An etching rate of the second insulating layer 120B is different from an etching rate of the second dielectric layers 112B. The second insulating layer 120B can include, for example but not limited to, a SiN insulating layer or a SiCN insulating layer. The second insulating layer 120B includes a second thickness T₂, and the second thickness T₂ is between 100 Å and 800 Å. Preferably, the second thickness T₂ of the second insulating layer 120B is between 300 Å, and 400 Å, but not limited to this. As mentioned above, the second insulating layer 120B usually is an etching stop layer in a planarization process for forming the second top metal layer 118B. Accordingly, the second wafer 100B includes a second front surface 104B (which is meanwhile a surface of the second insulating layer 120B and a surface of the second top metal layer 118B) and a second back surface 106B opposite to the second front surface 104B, as shown in FIG. 1B. It should be easily realized that the second top metal layer 118B serves as an external contact pads allowing the second wafer 100B being electrically connected to other structure/circuitry/wafer. Therefore, the second top metal layer 118B is exposed on the second front surface 104B. Additionally speaking, the surface of the second top metal layer 118B and the surface of the second insulating layer 120B are coplanar.

Please refer to FIG. 2. The first wafer 100A and the second wafer 100B are then to be bonded. It should be noted that the first wafer 100A and the second wafer 100B are face-to-face bonded. That is, the first front surface 104A of the first wafer 100A contacts the second front surface 104B of the second wafer 100B. It other words, the first insulating layer 120A and the second insulating layer 120B contact each other, and the first top metal layer 118A and the second top metal layer 118B also contact each other. It is noteworthy that an initial Van der Waals bonding process can be performed before an anneal bonding process. The Van der Waals force is usually defined as the sum of the attractive and repulsive forces between molecules and atoms other than those due to chemical or atomic bonding between molecules and atoms. The Van der Waals force is a relatively weak force, therefore wafer alignment test is usually performed in the initial Van der Waals bonding process and followed by downstream bonding process, such as the above mentioned anneal bonding process. As shown in FIG. 2, finally, the first wafer 100A and the second wafer 100B are face-to-face bonded, and a stacked semiconductor structure 150 such as a 3D-IC is obtained.

Please still refer to FIG. 2. It is noteworthy that the first wafer 100A and the second wafer 100B are not always precisely and accurately aligned. When the first wafer 100A and the second wafer 100B are misaligned, the first insulating layer 120A contacts a portion of the second top metal layer 118B and the second insulating layer 120B contact a portion of the first top metal layer 118A according to the preferred embodiment. Therefore, contact between the first dielectric layer 112A and the second top metal layer 118B is completely avoided and contact between the second dielectric layer 112B and the first top metal layer 118A is also completely avoided. That is, metal diffusions to the first and second dielectric layers 112A/112B are prevented by the first insulating layer 120A and the second insulating layer 120B.

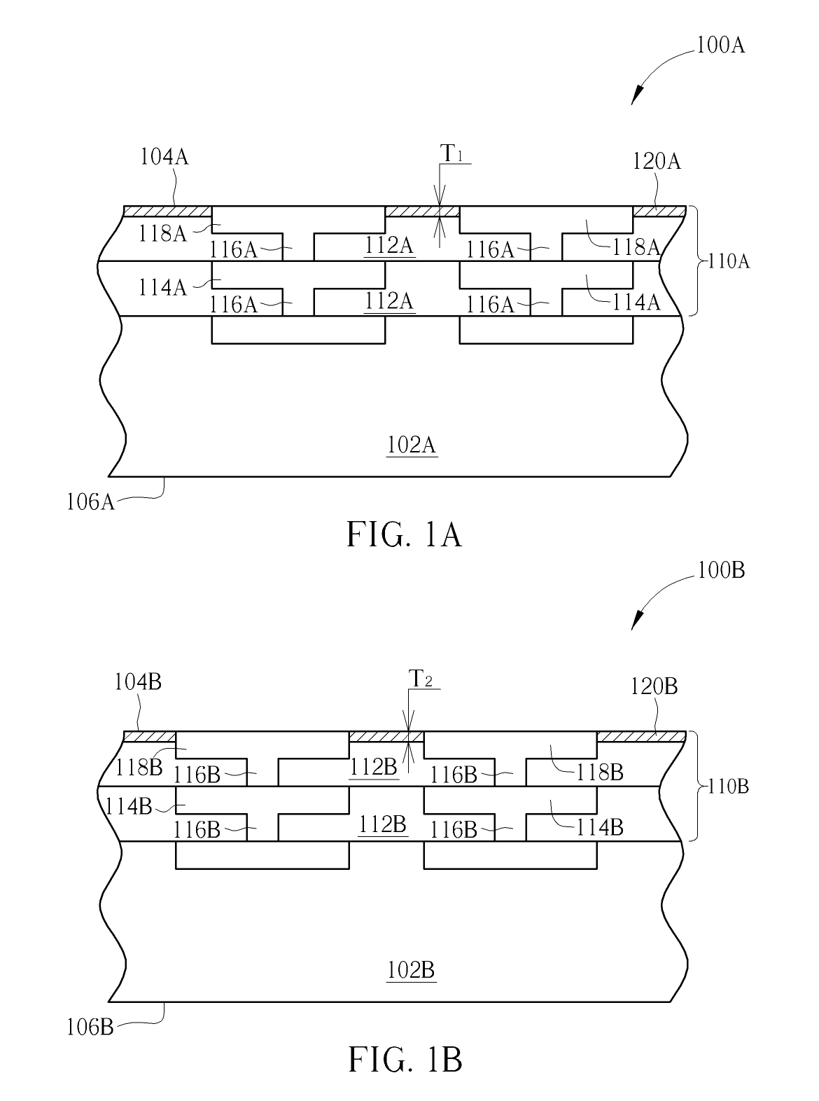

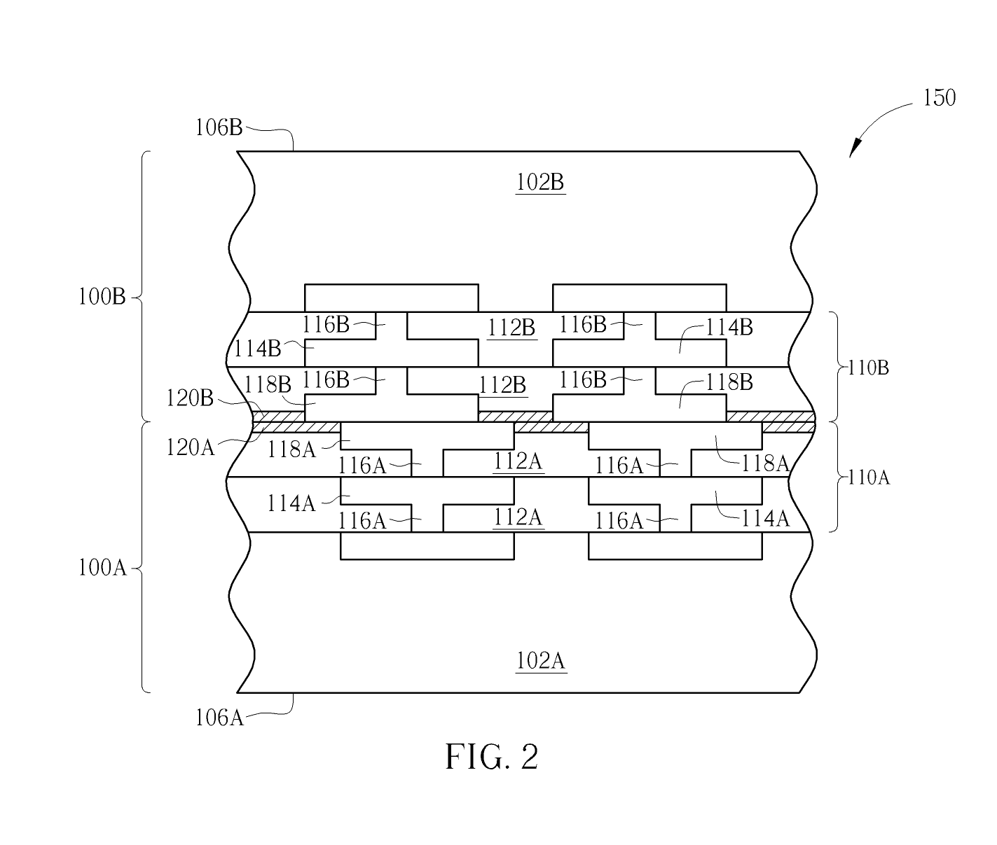

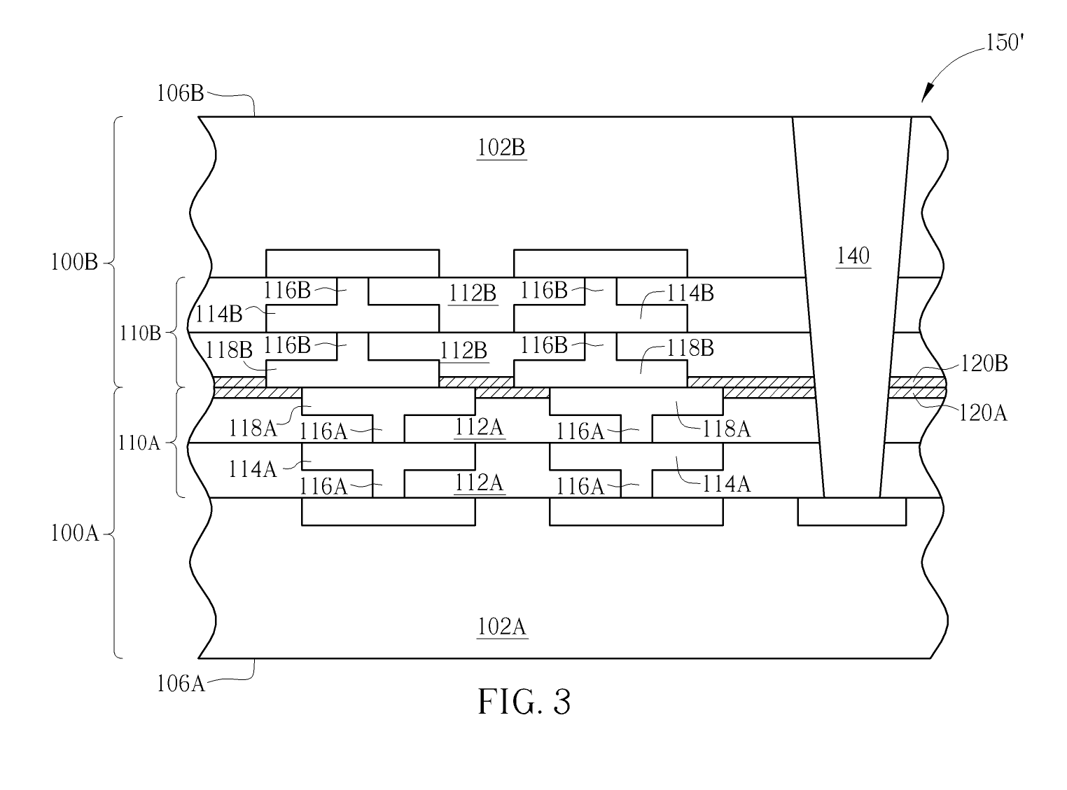

Please refer to FIG. 3, which is a schematic drawing illustrating a stacked semiconductor structure provided by a modification to the first preferred embodiment of the present invention. It should be noted that elements the same in the modification and the first preferred embodiment are designated by the same numerals and those related details are omitted in the interest of brevity. As shown in FIG. 3, the difference between the modification and the first preferred embodiment is: the stacked semiconductor structure 150′ provided by the modification further includes at least a through-silicon-via (hereinafter abbreviated as TSV) structure 140 penetrating the first wafer 100A and the second wafer 100B.

It is well-known to those skilled in the art that with progress in semiconductor manufacturing technology, a multitude of chips may now be integrated into one single package. And in a single package, the connection between chips is realized by TSV structures. Therefore, the TSV structure 140 penetrating the second substrate 102B, the second interconnection structure 110B, the second insulating layer 120B, the first insulating layer 120A, and the first interconnection structure 110A is provided.

The TSV structure 140 can formed by deep etching into the wafers 100A/100B, and filling the resulting hole with a liner and a conductive filling layer. Then, the second wafer 100B is thinned from its back surface 106B, until the conductive filling layer is exposed, and a backside metal and bumps are deposited on the thinned backside for electrical contact.

According to the stacked semiconductor structure 150 and 150′ provided by the first preferred embodiment and its modification, a solid insulating layer 120A/120B is sandwiched between the first front surface 104A of the first wafer 100A and the second front surface 104B of the second wafer 104B . When the first wafer 100A and the second wafer 100B are misaligned, the solid insulating layer 120A/120B contacts the surface of the first top metal layer 118A and the surface of the second top metal layer 118B. Consequently, contact between the top metal layers 118A/118B and the dielectric layers 112B/112A are completely avoided and thus metal diffusion is prevented. Therefore, electrical performance of the stacked semiconductor structure 150/150′ is improved. Additionally, the TVS structure 140 can be adopted to provide further electrical connections between the first wafer 100A and the second wafer 100B.

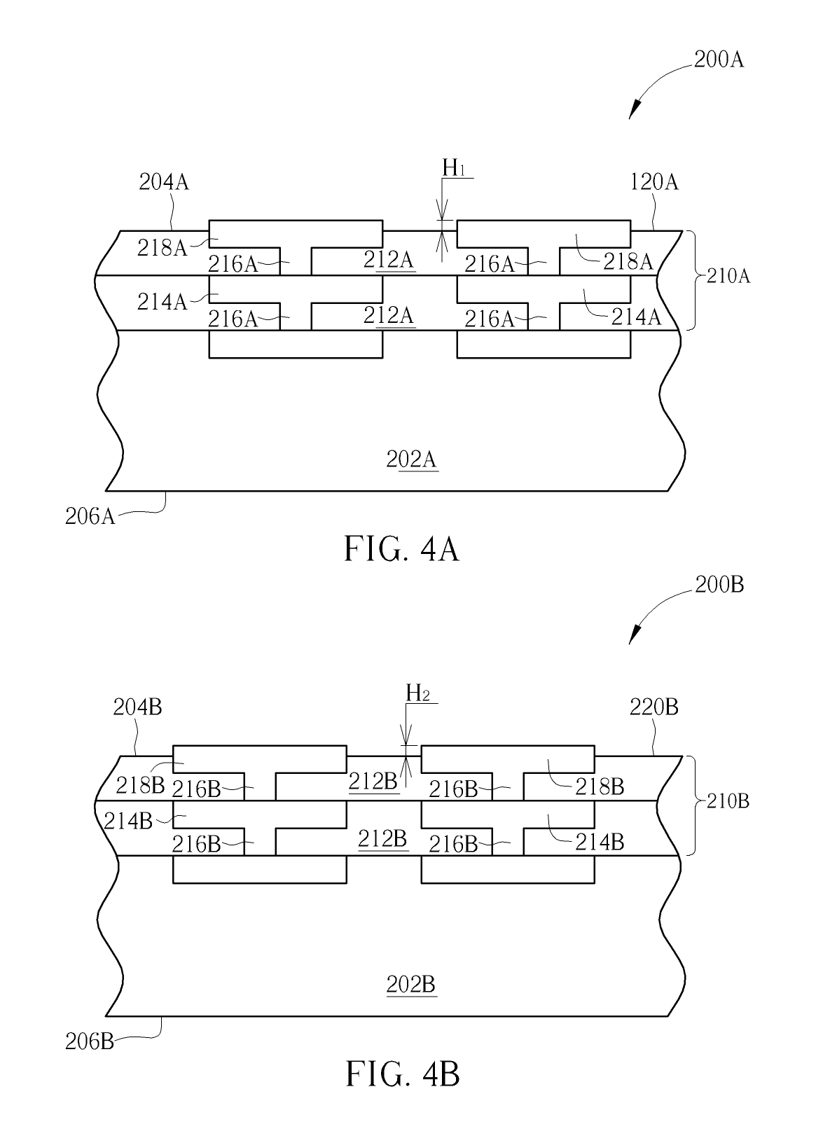

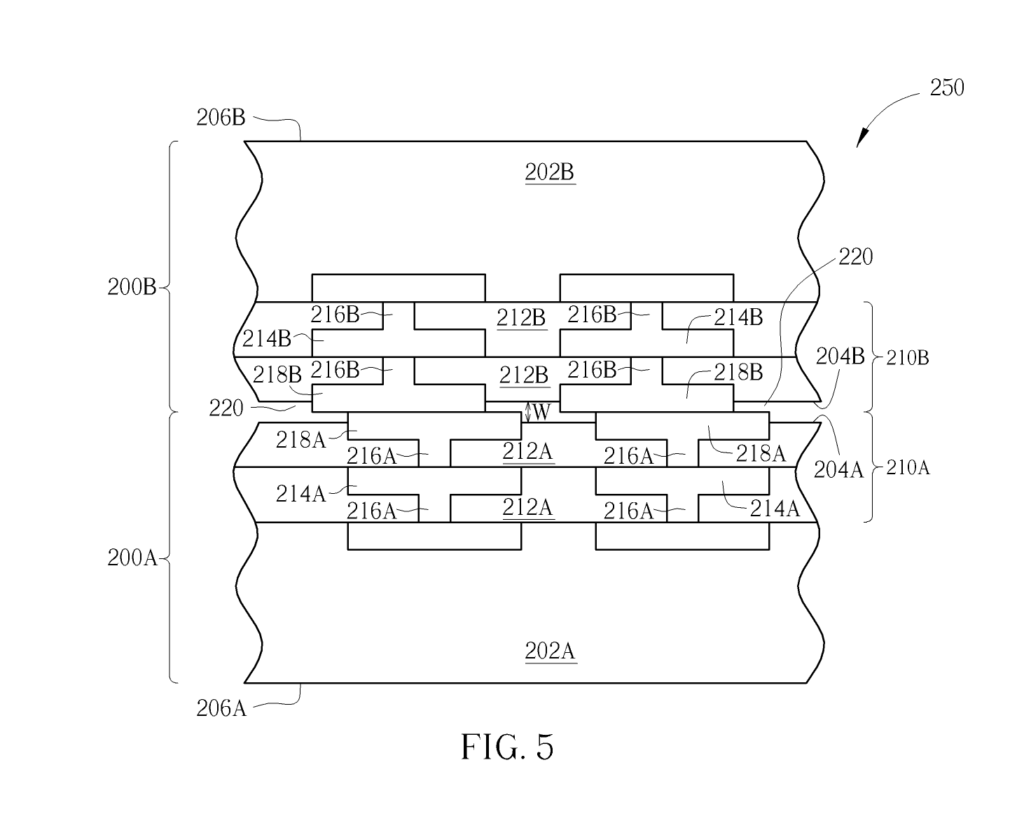

Please refer to FIGS. 4A, 4B and 5, which are drawings illustrating a stacked semiconductor structure provided by a second preferred embodiment of the present invention. As shown in FIG. 4A and FIG. 4B, the preferred embodiment provides a first wafer 200A and a second wafer 200B. The first wafer 200A and the second wafer 200B are to be bonded to form a stacked semiconductor structure such as a 3D-IC according to the preferred embodiment. The first wafer 200A can include a first substrate 202A, and at least an electronic circuitry (not shown) is formed in the first substrate 202A.

As mentioned in the first preferred embodiment, the electronic circuitry formed in the first substrate 202A includes circuitry for constructing any specific device/structure such as, for example but not limited to, memory structures, processing structures, sensors, amplifiers, power distribution, input/output circuitry, or the like. Generally, the electronic circuitry includes semiconductor devices (not shown) such as nMOS transistor devices and pMOS transistor devices, capacitors, resistor, diodes, fuses and any suitable devices. Those semiconductor devices may be electrically connected to perform one or more functions. The first wafer 200A further includes a first interconnection structure 210A providing the abovementioned electrical connections between the devices or electrical connections to external circuitry.

Please still refer to FIG. 4A, the first interconnection structure 210A includes a plurality of first dielectric layers 212A. The first dielectric layers 212A includes, low-K dielectric material, SiO, PSG, BPSG, FSG, or TEOS, but not limited to this. The first interconnection structure 210A includes a plurality of first metal layers 214A formed in the first dielectric layers 212A, a plurality of first via plugs 216A formed in the first dielectric layers 212A, and at least a first top metal layer 218A. As shown in FIG. 4A, the first via plugs 216A electrically connect the first metal layers 214A and the first top metal layer 218A. The manufacturing process and material choice of the first metal layers 214A, the first via plugs 216A and the first top metal layer 218A can be the same with those described in the first preferred embodiment, therefore those details are also omitted for simplicity.

Please still refer to FIG. 4A. It is well-known that an insulating layer can be formed to serve as an etching stop layer in a planarization process for forming the first top metal layer 218A. In the preferred embodiment, that specific etching stop layer is removed after the planarization, therefore the first top metal layer 218A is protruded from a first front surface 204A of the first wafer 200A, that is, the first top metal layer 218A is protruded from a surface of the first dielectric layer 212A. Accordingly, the first top metal layer 218A includes a first protruded height H₁. The first protruded height H₁ is between 100 Å and 800 Å. Preferably, the first protruded height H₁ is between 300 Å and 400 Å, but not limited to this . Accordingly, the first wafer 200A includes a first front surface 204A (which is meanwhile the surface of the first dielectric layer 212A) and a first back surface 206A opposite to the first front surface 204A, as shown in FIG. 4A. It should be easily realized that the first top metal layer 218A serves as an external contact pads allowing the first wafer 200A being electrically connected to other structure/circuitry/wafer.

Please refer to FIG. 4B. The second wafer 200B can include a second substrate 202B, and at least an electronic circuitry (not shown) is formed in the second substrate 202B. The electronic circuitry formed in the second substrate 202B includes circuitry for constructing any specific device/structure such as, for example but not limited to, memory structures, processing structures, sensors, amplifiers, power distribution, input/output circuitry, or the like. According to the preferred embodiment, the second substrate 202B can include BSI sensors, but not limited to. The second wafer 200B further includes a second interconnection structure 210B providing the electrical connections between the devices or electrical connections to external circuitry.

Please still refer to FIG. 4B, the second interconnection structure 210B includes a plurality of second dielectric layers 212B. The second dielectric layers 212B can include material the same with those used to form the first dielectric layers 212A, therefore those details are omitted herein in the interest of brevity. The second interconnection structure 210B includes a plurality of second metal layers 214B formed in the second dielectric layers 212B, a plurality of second via plugs 216B formed in the second dielectric layers 212B, and at least a second top metal layer 218B. As shown in FIG. 4B, the second via plugs 216B electrically connect the second metal layers 214B and the second top metal layer 218B. The manufacturing process and material choice of the second metal layers 214B, the second via plugs 216B and the second top metal layer 218B can be the same with those described in the first preferred embodiment, therefore those details are also omitted for simplicity.

Please still refer to FIG. 4B. As mentioned above, an insulating layer can be formed to serve as an etching stop layer in a planarization process for forming the second top metal layer 218B. In the preferred embodiment, that specific etching stop layer is removed after the planarization, therefore the second top metal layer 218B is protruded from a second front surface 204B of the second wafer 200B, that is, the second top metal layer 218B is protruded from a surface of the second dielectric layer 212B. Accordingly, the second top metal layer 218B includes a second protruded height H₂ . The second protruded height H₂ is between 100 Å and 800 Å. Preferably, the second protruded height H₂ is between 300 Å and 400 Å, but not limited to this. Accordingly, the second wafer 200B includes a second front surface 204B (which is meanwhile the surface of the second dielectric layer 212B) and a second back surface 206B opposite to the second front surface 204B, as shown in FIG. 4B. It should be easily realized that the second top metal layer 218B serves as an external contact pads allowing the second wafer 200B being electrically connected to other structure/circuitry/wafer.

Please refer to FIG. 5. The first wafer 200A and the second wafer 200B are then to be bonded. It should be noted that the first wafer 200A and the second wafer 200B are face-to-face bonded. That is, the first front surface 204A of the first wafer 200A faces the second front surface 204B of the second wafer 200B. More important, since the first top metal layer 218A is protruded from the first front surface 204A of the first wafer 200A and the second top metal layer 218B is protruded from the second front surface 204B of the second wafer 200B, the first top metal layer 218A directly contacts the second top metal layer 218B in accordance with the preferred embodiment. As shown in FIG. 5, finally, a stacked semiconductor structure 250 such as a 3D-IC is obtained. More important, a gap 220 is sealed in between the first wafer 200A and the second wafer 200B as shown in FIG. 5. That is, the gap 220 is formed between the first front surface 204A of the first wafer 200A and the second front surface 204B of the second wafer 200B. Additionally, the gap 220 includes a width W, and the width W of the gap 220 is a sum of the first protruded height H₁ and the second protruded height H₂.

Please still refer to FIG. 5. It is noteworthy that the first wafer 200A and the second wafer 200B are not always precisely and accurately aligned. When the first wafer 200A and the second wafer 200B are misaligned, the first top metal layer 218A is exposed in the gap 220 and the second metal layer 218B is exposed in the gap 220 according to the preferred embodiment. Accordingly, contact between the first dielectric layer 212A and the second top metal layer 218B is completely avoided and contact between the second dielectric layer 212B and the first top metal layer 218A is also completely avoided. Therefore, metal diffusions to the first and second dielectric layers 212A/212B are prevented by the gap 220.

According to the stacked semiconductor structure 250 provided by the second preferred embodiment, a gap 220 is formed in between the first wafer 200A and the second wafer 204B. It is well-known that air in the gap 220 serves as superior dielectric material, therefore it is taken that an air insulating layer 220 is formed between the first front surface 204A of the first wafer 200A and the second front surface 204B of the second wafer 204B. When the first wafer 200A and the second wafer 200B are misaligned, the air insulating layer 220 contacts all of the exposed surfaces of the first top metal layer 218A and all of the exposed surfaces of the second top metal layer 218B. Consequently, contact between the top metal layers 218A/218B and the dielectric layers 212B/212A are completely avoided and thus metal diffusion is prevented. Therefore, electrical performance of the stacked semiconductor structure 250 is improved.

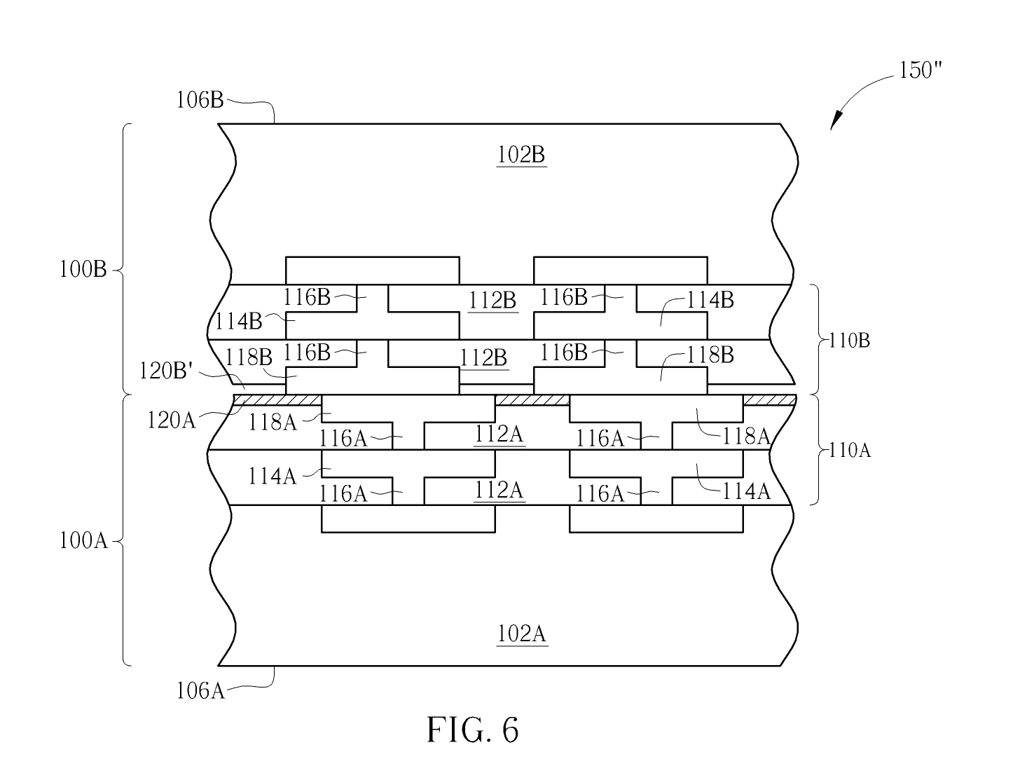

Please refer to FIG. 6, which is a schematic drawing illustrating a stacked semiconductor structure provided by a modification to the first and second preferred embodiments of the present invention. It should be noted that elements the same in the modification and the first preferred embodiment are designated by the same numerals and those related details are omitted in the interest of brevity. As shown in FIG. 6, the difference between the modification and the first/second preferred embodiment is: the first wafer 100A includes a first insulating layer 120A formed on a first interconnection structure 110A, however the second wafer 100B includes a second top metal layer 118B protruded from a second front surface 104B of the second wafer 100B.

Therefore, when the first wafer 100A and the second wafer 100B are face-to-face bonded, the first insulating layer 120A contacts the second top metal layer 118B while the second top metal layer 118B is exposed in a gap 120B between the first wafer 100A and the second wafer 100B when the first wafer 100A and the second wafer 100B are misaligned. Accordingly, a multiple insulating layer including the air insulating layer sealed in the gap 120B and the solid first insulating layer 120A is obtained. Consequently, contact between the top metal layers 118A/118B and the dielectric layers 112B/112A are completely avoided and thus metal diffusion is prevented. Therefore, electrical performance of the stacked semiconductor structure 150″ is improved.

According to the stacked semiconductor structure provided by the present invention, an insulating layer is always formed in between the first front surface of the first wafer and the second front surface of the second wafer. The insulating layer can be a solid insulating layer, an air insulating layer, or a multiple insulating layer including both solid and air insulating layers. More important, the insulating layer serves as a superior barrier for metal diffusion. Accordingly, in a case that the first wafer and the second wafer are unwantedly misaligned, the solid insulating layer, the air insulating layer or the multiple insulating layer prevents metal diffusion between the two bonded wafers. And thus electrical performance of the stacked semiconductor structure is improved. Additionally, though the stacked semiconductor structure provided by the present invention includes wafer-to-wafer bonded structure, the stacked semiconductor structure can be a die-to-wafer bonded structure or die-to-die bonded structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A stacked semiconductor structure comprising:
a first wafer comprising a first front surface, a first back surface opposite to the first front surface, and a first interconnection structure formed in the first wafer, the first interconnection structure comprising at least a first top metal layer exposed on the first front surface of the first wafer;
a second wafer comprising a second front surface, a second back surface opposite to the second front surface, and a second interconnection structure formed in the second wafer, the second interconnection structure comprising at least a second top metal layer exposed on the second front surface of the second wafer;
a first insulating layer formed on the first front surface of the first wafer; and
a second insulating layer formed on the second front surface of the second wafer, the first insulating layer and the second insulating layer contacting each other.

2. The stacked semiconductor structure according to claim 1, wherein the first insulating layer and the second insulating layer respectively comprise a silicon nitride (SiN) insulating layer or a silicon carbon nitride (SiCN) insulating layer.

3. The stacked semiconductor structure according to claim 1, wherein the first interconnection structure comprises a plurality of first dielectric layers, a plurality of first metal layers formed in the first dielectric layers and a plurality of first via plugs formed in the first dielectric layers, and the second interconnection structure comprises a plurality of second dielectric layers, a plurality of second metal layers formed in the second dielectric layers and a plurality of second via plugs formed in the second dielectric layers.

4. The stacked semiconductor structure according to claim 3, wherein the first via plugs electrically connect the first metal layers and the first top metal layer, and the second via plugs electrically connect the second metal layers and the second top metal layer.

5. The stacked semiconductor structure according to claim 3, wherein an etching rate of the first insulating layer is different from an etching rate of the first dielectric layers, and an etching rate of the second insulating layer is different from an etching rate of the second dielectric layers.

6. The stacked semiconductor structure according to claim 5, wherein the first dielectric layers and the second dielectric layers comprise silicon oxide (SiO).

7. The stacked semiconductor structure according to claim 6, wherein the first insulating layer and the second insulating layer respectively comprise an air insulating layer.

8. The stacked semiconductor structure according to claim 1, wherein the first insulating layer and the second insulating layer respectively comprise a thickness, and the thickness is between 100 angstroms (Å) and 800 Å.

9. The stacked semiconductor structure according to claim 1, wherein a surface of the first top metal layer and a surface of the first insulating layer are coplanar, and a surface of the second top metal layer and a surface of the second insulating layer are coplanar.

10. The stacked semiconductor structure according to claim 1, wherein the first insulating layer contacts a portion of the second top metal layer and the second insulating layer contact a portion of the first top metal layer.

11. A stacked semiconductor structure comprising:
a first wafer comprising a first front surface and a first back surface opposite to each other;
a second wafer comprising a second front surface and a second back surface opposite to each other;
a first interconnection structure formed in the first wafer, the first interconnection structure comprising at least a first top metal layer protruded from the first front surface of the first wafer; and
a second interconnection structure formed in the second wafer, the second interconnection structure comprising at least a second top metal layer protruded from the second front surface of the second wafer, the second top metal layer directly contacting the first top metal layer.

12. The stacked semiconductor structure according to claim 11, further comprising a gap formed between the first front surface of the first wafer and the second front surface of the second wafer.

13. The stacked semiconductor structure according to claim 12, wherein the gap comprises a width, the first top metal layer comprises a first protruded height, and the second top metal layer comprises a second protruded height, and the width of the gap is a sum of the first protruded height and the second protruded height.

14. The stacked semiconductor structure according to claim 11, wherein the first interconnection structure comprises a plurality of first dielectric layers, a plurality of first metal layers formed in the first dielectric layers and a plurality of first via plugs formed in the first dielectric layers, and the second interconnection structure comprises a plurality of second dielectric layers, a plurality of second metal layers formed in the second dielectric layers and a plurality of second via plugs formed in the second dielectric layers.

15. The stacked semiconductor structure according to claim 14, wherein the first via plugs electrically connect the first metal layers and the first top metal layer, and the second via plugs electrically connect the second metal layers and the second top metal layer.

16. The stacked semiconductor structure according to claim 14, wherein the first dielectric layers and the second dielectric layers comprise SiO.

17. A stacked semiconductor structure comprising:
a first wafer comprising a first front surface, a first back surface opposite to the first front surface, and a first interconnection structure formed in the first wafer, the first interconnection structure comprising at least a first top metal layer exposed on the first front surface of the first wafer;
a second wafer comprising a second front surface, a second back surface opposite to the second front surface, and a second interconnection structure formed in the second wafer, the second interconnection structure comprising at least a second top metal layer exposed on the second front surface of the second wafer;
a solid insulating layer sandwiched between the first front surface of the first wafer and the second front surface of the second wafer; and
a through-silicon-via (TSV) structure penetrating the first wafer and the second wafer.

18. The stacked semiconductor structure according to claim 17, wherein the solid insulating layer comprises a SiN insulating layer or a SiCN insulating layer.

19. The stacked semiconductor structure according to claim 17, wherein the solid insulating layer contacts a surface of the first top metal layer and a surface of the second top metal layer.

20. The stacked semiconductor structure according to claim 17, wherein the first interconnection structure comprises a plurality of first dielectric layers, a plurality of first metal layers formed in the first dielectric layers and a plurality of first via plugs formed in the first dielectric layers, the second interconnection structure comprises a plurality of second dielectric layers, a plurality of second metal layers formed in the second dielectric layers and a plurality of second via plugs formed in the second dielectric layers, and an etching rate of the solid insulating layer is different from an etching rate of the first dielectric layers and the second dielectric layers.
